(19) United States
(12) Patent Application Publication
(10) Pub. No.: US 2024/0321830 A1
(43) Pub. Date: Sep. 26, 2024

(54) MANUFACTURING METHOD OF SEMICONDUCTOR DEVICE AND SEMICONDUCTOR DEVICE

(71) Applicant: Kioxia Corporation, Tokyo (JP)

(72) Inventors: Hayato FURUICHI, Yokkaichi Mie (JP); Yuusuke TAKANO, Yokkaichi Mie (JP); Tatsuo MIGITA, Nagoya Aichi (JP)

(21) Appl. No.: 18/596,484

(22) Filed: Mar. 5, 2024

(30) Foreign Application Priority Data
Mar. 20, 2023 (JP) 2023-043865

(51) Int. Cl. H01L 25/065; H01L 21/56; H01L 21/78; H01L 23/00; H01L 23/31; H01L 23/544

(52) U.S. Cl. CPC H01L 25/0657; H01L 21/561; H01L 21/78; H01L 23/3107; H01L 23/544; H01L 24/16; H01L 24/81; H01L 24/94; H01L 2223/54426; H01L 2224/16145; H01L 2224/81; H01L 2224/94; H01L 2225/06541

(57) ABSTRACT

A manufacturing method of a semiconductor device, includes mounting on a first substrate a plurality of second substrates at a predetermined interval, the first substrate including a wiring layer, each of the second substrates including a plurality of semiconductor cells separated from each other by a boundary portion, forming a first recess on the first substrate between two of the second substrates that are adjacent to each other, cutting each of the second substrates along the boundary portion thereof to form a gap and a second recess on the first substrate through the gap, forming a sealing member on the first substrate, and cutting the first substrate together with the sealing member along lines extending along and inside the first and second recesses to individualize the semiconductor cells.

### CROSS-REFERENCE TO RELATED APPLICATION(S)

This application is based upon and claims the benefit of priority from Japanese Patent Application No. 2023-043865, filed Mar. 20, 2023, the entire contents of which are incorporated herein by reference.

### FIELD

Embodiments described herein relate generally to a manufacturing method of a semiconductor device, and the semiconductor device.

### BACKGROUND

In a manufacturing process for a semiconductor device in which a semiconductor chip is sealed, the semiconductor chip attached onto a resin film is sometimes picked up by a picker or the like and mounted on a substrate. At this time, for example, when the semiconductor chip is thin and has a long slender shape, the semiconductor chip may be tilted or damaged during the pickup. Consequently, a proper electrical connection of the semiconductor device cannot be established, thereby reducing yields. Moreover, since multiple semiconductor chips are individually mounted on the substrate, processing time may become longer and productivity may decrease.

### BRIEF DESCRIPTION OF THE DRAWINGS

FIG. 1A is a diagram illustrating a configuration of a semiconductor device according to an embodiment.

FIG. 1B is a diagram illustrating the configuration of the semiconductor device.

FIG. 2 is a top view diagram schematically illustrating a configuration of a composite cell substrate mounted on a substrate, in a manufacturing method of the semiconductor device.

FIG. 3A is a diagram illustrating in order a part of the manufacturing method of the semiconductor device.

FIG. 3B is a diagram illustrating in order a part of the manufacturing method of the semiconductor device.

FIG. 4 is a schematic diagram illustrating a position alignment between the substrate and the composite cell substrate, in the procedure of the manufacturing method of the semiconductor device.

FIG. 5A is a diagram illustrating in order a part of the manufacturing method of the semiconductor device.

FIG. 5B is a diagram illustrating in order a part of the manufacturing method of the semiconductor device.

FIG. 6A is a diagram illustrating in order a part of the manufacturing method of the semiconductor device.

FIG. 6B is a diagram illustrating in order a part of the manufacturing method of the semiconductor device.

FIG. 7A is a diagram illustrating a part of a manufacturing method of a semiconductor device according to a modified example 1.

FIG. 7B is a diagram illustrating a part of the manufacturing method of the semiconductor device according to the modified example 1.

FIG. 8A is a diagram illustrating a part of a manufacturing method of a semiconductor device according to a modified example 2.

FIG. 8B is a diagram illustrating a part of the manufacturing method of the semiconductor device according to the modified example 2.

FIG. 9A is a diagram illustrating a configuration of a semiconductor device according to a modified example 3.

FIG. 9B is a diagram illustrating a configuration of the semiconductor device according to the modified example 3.

FIG. 10 is a diagram illustrating a configuration of a semiconductor device according to a modified example 4.

FIG. 11A is a diagram illustrating a part of a manufacturing method of a semiconductor device according to a modified example 5.

FIG. 11B is a diagram illustrating a part of the manufacturing method of the semiconductor device according to the modified example 5.

FIG. 12A is a diagram illustrating a part of a manufacturing method of a semiconductor device according to a modified example 6.

FIG. 12B is a diagram illustrating an application example of the semiconductor device.

FIG. 13 is a diagram illustrates in order a part of the manufacturing method of a semiconductor device according to a modified example 7.

FIG. 14 is a diagram illustrates in order a part of the manufacturing method of the semiconductor device according to the modified example 7.

FIG. 15A is a diagram illustrating a configuration of the semiconductor device according to the modified example 7.

FIG. 15B is a diagram illustrating the configuration of the semiconductor device according to the modified example 7.

FIG. 15C is a diagram illustrating the configuration of the semiconductor device according to the modified example 7.

FIG. 16A is a diagram illustrating a part of a manufacturing method of a semiconductor device according to a modified example 8.

FIG. 16B is a diagram illustrating a part of the manufacturing method of the semiconductor device according to the modified example 8.

FIG. 17A is a diagram illustrating a part of the manufacturing method of the semiconductor device according to the modified example 8.

FIG. 17B is a diagram illustrating a part of the manufacturing method of the semiconductor device according to the modified example 8.

FIG. 18A is a diagram illustrating a configuration of a semiconductor device according to a comparative example.

FIG. 18B is a diagram illustrating a configuration of the semiconductor device according to the comparative example.

### DETAILED DESCRIPTION

Embodiments provide a manufacturing method of a semiconductor device and the semiconductor device, capable of improving a yield and productivity of the semiconductor device.

In general, according to one embodiment, a manufacturing method of a semiconductor device comprises: mounting on a first substrate a plurality of second substrates at a predetermined interval, the first substrate including a wiring layer, each of the second substrates including a plurality of semiconductor cells separated from each other by a boundary portion; forming a first recess on the first substrate between two of the second substrates that are adjacent to each other; cutting each of the second substrates along the boundary portion thereof to form a gap and a second recess on the first substrate through the gap; forming a sealing member on the first substrate; and cutting the first substrate together with the sealing member along lines extending along and inside the first and second recesses to individualizing the semiconductor cells.

Certain embodiments will now be described in detail with reference to drawings. The present disclosure is not limited to the following embodiments. Moreover, the components in the following embodiments include those that can be easily conceived by persons skilled in the art or are substantially identical.

### EMBODIMENTS

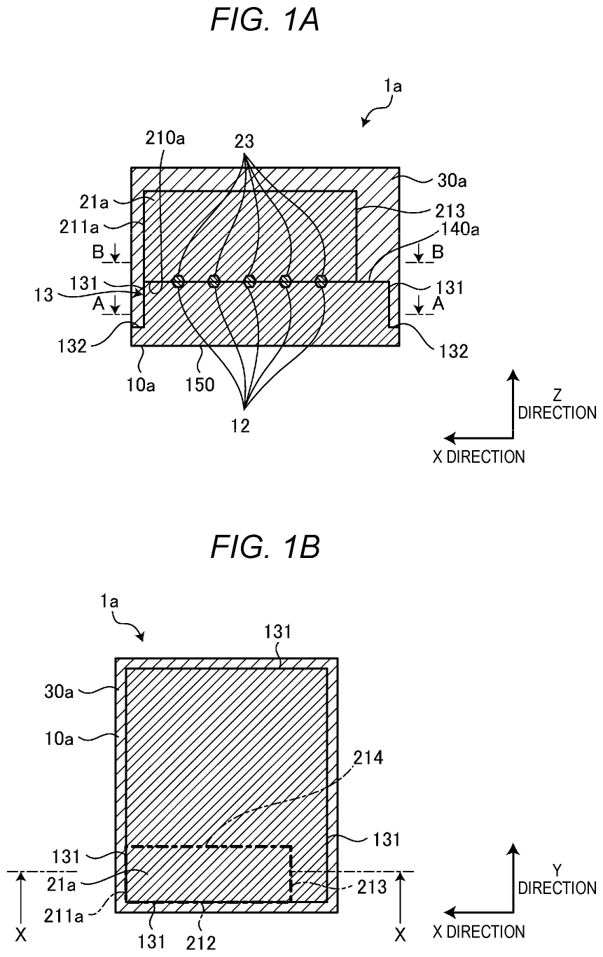

Hereinafter, embodiments will be described in detail with reference to FIGS. 1 to 6.

### Configuration Example of Semiconductor Device

FIGS. 1A and 1B are diagrams each illustrating a configuration of a semiconductor device 1a according to an embodiment. FIG. 1A is an XZ cross-sectional diagram illustrating the semiconductor device 1a. The XZ cross-sectional diagram in FIG. 1A is taken along the line X-X illustrated in FIG. 1B. FIG. 1B is an XY cross-sectional diagram taken along the line A-A illustrated in FIG. 1A. Moreover, an outline illustrated by a chain line in FIG. 1B corresponds to an outside shape of a cell 21a cut out by the line B-B in FIG. 1A.

In this specification, a direction in which a bottom surface 150 of a substrate 10a in the semiconductor device 1a faces defined downward, and a direction in which the cell 21a is stacked as observed from the substrate 10a is defined as upward. That is, the up-and-down direction of the semiconductor device 1a is referred to as a stacked direction along the Z direction. The X direction is a direction along an orientation of a surface of the substrate 10a, and the X direction and the Z direction are directions orthogonal to each other. Directions indicated by the arrows of the X-axis and the Z-axis are respectively a positive X direction and a positive Z direction, and opposite directions to the arrows are respectively a negative X direction and a negative Z direction. The Y direction is a direction orthogonal to each of the X direction and the Z direction in FIGS. 1A and 1B.

In the present embodiment, the semiconductor device 1a is configured as a three-dimensional nonvolatile memory including memory cells arranged in three dimensions. As illustrated in FIGS. 1A and 1B, the semiconductor device 1a includes the substrate 10a, the cell 21a, and a sealing member 30a. The cell 21a is not limited to the three-dimensional nonvolatile memory, but may be any type of volatile memory, image sensor, logic circuit, or the like.

The substrate 10a is, for example, a silicon substrate or the like, and includes peripheral circuits, as a wiring layer, including a transistor which is not illustrated. The peripheral circuits are covered by an insulation layer. Specifically, the transistor formed on the substrate 10a is connected to an upper wiring via a contact which is not illustrated, and the upper wiring is further connected to a terminal 12. The terminal 12 is exposed on an upper surface of the insulation layer, i.e., an upper surface 140a of the substrate 10a. In other words, the peripheral circuit is formed in the substrate 10a from the upper surface 140a to a predetermined depth.

The substrate 10a is formed in a rectangular shape when viewed in the stacked direction. A recess 13 is formed in a part of the outer peripheral portion of the substrate 10a by digging down the substrate 10a to a predetermined position toward the negative Z direction. The recess 13 has a side surface 131 bent from the upper surface 140a of the substrate 10a, and an upper surface 132 extending outward substantially parallel to the upper surface 140a from a lower end of the side surface 131.

The cell 21a is a small piece, such as a silicon substrate. Although not illustrated, the cell 21a has a stacked structure in which a plurality of conductive layers are stacked with an insulation layer interposed therebetween, and memory cells are arranged in a matrix shape in the stacked structure. The conductive layer is connected to a wiring extending in the stacked direction via the contact which is not illustrated, and the wiring is connected to a terminal 23. The terminal 23 is exposed on a substrate surface 210a of the cell 21a.

The cell 21a is formed in a rectangular shape when viewed in the stacked direction and facing outward, and a periphery thereof is defined by side surfaces 211a to 214 adjacent one another. The cell 21a is disposed in a state where the substrate surface 210a thereof facing the upper surface 140a of the substrate 10a.

The terminal 23 exposed on the substrate surface 210a of the cell 21a is bonded to the terminal 12 exposed on the upper surface 140a of the substrate 10a. That is, the cell 21a and the substrate 10a are electrically connected to each other via the terminals 12 and 23b.

The cell 21a is bonded to the substrate 10a.

Moreover, when viewed in the stacked direction, the two surfaces, i.e., the side surface 211a and the side surface 212 adjacent to the side surface 211a of the cell 21a are located on the same plane of the side surface 131 of the substrate 10a. Furthermore, when viewed in the stacked direction, the side surface 213 opposite to the side surface 211a and the side surface 214 opposite to the side surface 212 are located inside the side surface 131 of the substrate 10a.

Herein, a length of the side surface 211a and the side surface 213 corresponding to a long side of the cell 21a is, for example, 12 mm or more. In contrast, a length of the side surface 212 and the side surface 214 corresponding to a short side of the cell 21a is, for example, not more than 3 mm. That is, a ratio between the short side and the long side of the cell 21a is 1:4 or more. A thickness in the Z direction of the cell 21a is, for example, not more than 40 μm.

The sealing member 30a is, for example, a thermosetting resin film such as an epoxy resin, an acrylic resin. The sealing member 30a covers the entire of the recess 13 and the cell 21a.

### Manufacturing Method of Semiconductor Device

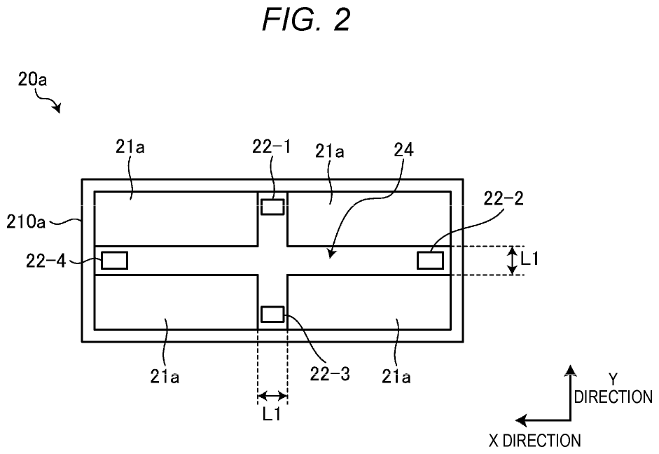

Next, a manufacturing method of the semiconductor device 1a will be described with reference to FIGS. 2 to 6.

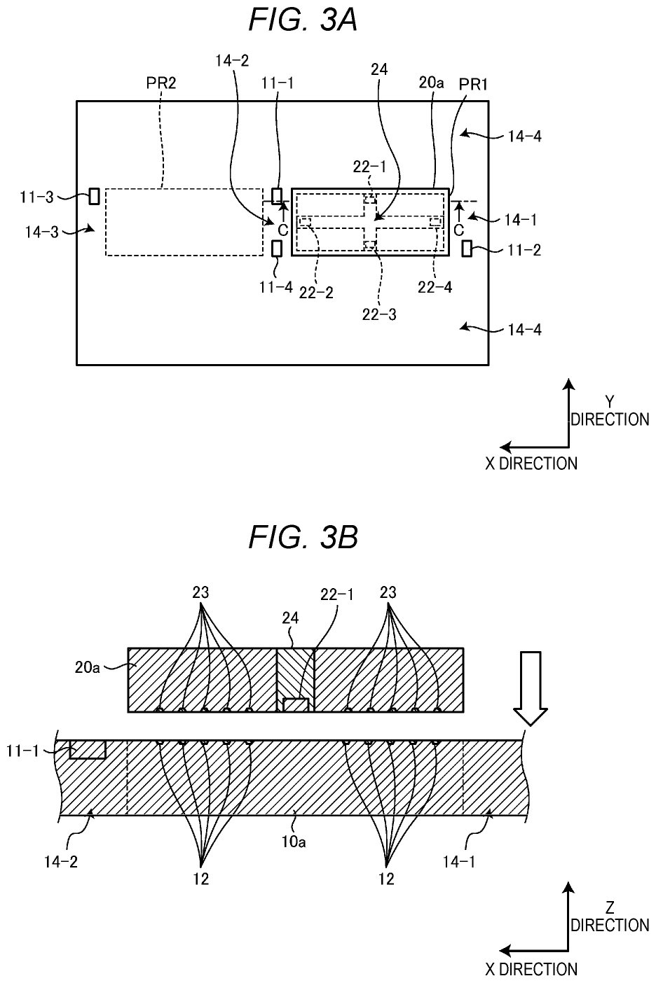

FIG. 2 is a top view diagram schematically illustrating a configuration of a composite cell substrate 20a mounted on the substrate 10a, in the manufacturing method of the semiconductor device 1a. In the manufacturing method of the semiconductor device 1a, a composite cell substrate 20a illustrated in FIG. 2 is prepared prior to a process illustrated in FIG. 3A.

The composite cell substrate 20a is, for example, a small piece, such as a silicon substrate, and has a plurality of cells 21a on a surface thereof. Specifically, as illustrated in FIG. 2, the cells 21a are disposed at intervals on the composite cell substrate 20a. The interval is referred to as a boundary portion 24.

The boundary portion 24 separates adjacent cells 21a from each other, and has a width L1, for example. Alignment marks 22-1 to 22-4 (hereinafter sometimes referred to as “alignment mark(s) 22”) for mounting the composite cell substrate 20a on the substrate 10a is formed inside the boundary portion 24.

Among the alignment marks 22-1 to 22-4, the alignment marks 22-2 and 22-4 are separated from each other in the positive and negative directions of X, and are arranged in a line along the X direction. The alignment marks 22-1 and 22-3 are separated from each other in the positive and negative directions of Y, and are arranged in a line along the Y direction. For example, copper (Cu) or the like is embedded in the alignment marks 22-1 to 22-4.

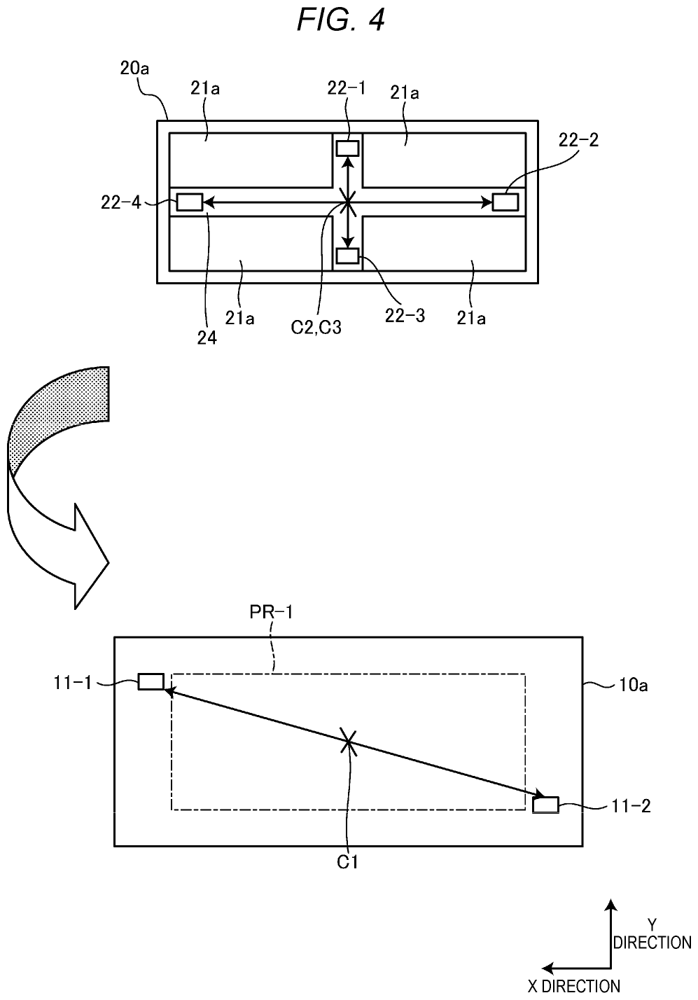

Next, the manufacturing method of the semiconductor device 1a using the above-described composite cell substrate 20a will be described with reference to FIGS. 3A to 6B. FIGS. 3A, 3B, 5A, 5B, 6A, and 6B are diagrams each illustrating in order a part of the manufacturing method of the semiconductor device 1a. FIG. 4 is a schematic diagram illustrating a position alignment between the substrate 10a and the composite cell substrate 20a, in the procedure illustrated in FIGS. 3A, 3B, 5A, 5B, 6A, and 6B.

FIGS. 3A and 3B are diagrams illustrating a process for mounting the composite cell substrate 20a on the substrate 10a of the procedure of the manufacturing method of the semiconductor device 1a. FIG. 3A is a top view diagram of the substrate 10a, which illustrates an aspect that the composite cell substrate 20a is mounted on a planned mounting region PR1. FIG. 3B is an XZ cross-sectional diagram taken along the line C-C in FIG. 3A.

First, prior to mounting of the composite cell substrate 20a, a peripheral circuit which is not illustrated is formed on the substrate 10a and is covered by an insulation layer. Moreover, the terminals 12 are exposed on each of the planned mounting regions PR1 and PR2 of the composite cell substrate 20a provided on the upper surface of the substrate 10a. The planned mounting regions PR1 and PR2 are arranged at predetermined intervals in X direction and the Y direction on the upper surface of the substrate 10a. Consequently, gap portions 14-1 to 14-4 (hereinafter sometimes referred to as “gap portions 14”) corresponding to the predetermined intervals is formed between the adjacent planned mounting regions PR.

Alignment marks 11-1 to 11-4 (hereinafter sometimes referred to as “alignment marks 11”) for mounting the composite cell substrate 20a are formed near each of the planned mounting regions PR1 and PR2 inside the gap portions 14-1 to 14-4.

For example, when the composite cell substrate 20a is mounted on the planned mounting region PR1, the alignment marks 11-1 and 11-2 corresponding to the planned mounting region PR1 is used. The alignment marks 11-1 and 11-2 are diagonal to each other outside the corresponding planned mounting region PR1.

At this time, for example, in the gap portion 14-2 between the planned mounting region PR1 and the planned mounting region PR2 disposed at a negative X direction side of the planned mounting region PR1, the alignment mark 11-1 corresponding to the planned mounting region PR1 and the alignment mark 11-4 corresponding to the planned mounting region PR2 are arranged in a line along the Y direction. Thus, each of the alignment marks 11 corresponding to each of the planned mounting regions PR1 and PR2 may be arranged in a line. In addition, for example, copper (Cu) or the like is embedded in each of the alignment marks 11-1 to 11-4.

FIG. 4 is a diagram illustrating the position alignment between the substrate 10a and the composite cell substrate 20a. The upper part of FIG. 4 illustrates a top view diagram of a composite cell substrate 20a to be mounted on the planned mounting region PR1 of the substrate 10a, and the lower part of FIG. 4 illustrates a top view diagram of the substrate 10a.

When the composite cell substrate 20a is mounted on the substrate 10a, a position alignment device which is not illustrated and capable of capturing two upper and lower visual fields is used. As illustrated in FIG. 4, the composite cell substrate 20a is held by the position alignment device in a state where upper and lower surfaces thereof are inverted from each other. Consequently, the surface of the composite cell substrate 20a on which the alignment marks 22-1 to 22-4 are formed and the surface of the substrate 10a on which the alignment marks 11-1 and 11-2 are formed face each other. Moreover, the alignment marks 11-1 and 11-2 and the alignment marks 22-1 to 22-4 are each captured by the position alignment device.

Position coordinates of each of the alignment marks 11-1 to 11-2 and 22-1 to 22-4 are detected on the basis of the captured images. Consequently, coordinates of the center point C1 between the alignment marks 11-1 and 11-2, coordinates of the center point C2 between the alignment marks 22-1 and 22-3, and coordinates of the center point C3 between the alignment marks 22-1 and 22-3 are calculated. Then, the substrate 10a and the composite cell substrate 20a are aligned with each other so that the center points C1 to C3 overlap in an up and down direction.

When the position alignment between the substrate 10a and the composite cell substrate 20a is successful in this manner and the terminal 12 and the terminal 23 are bonded to each other, the substrate 10a and the composite cell substrate 20a are electrically connected to each other.

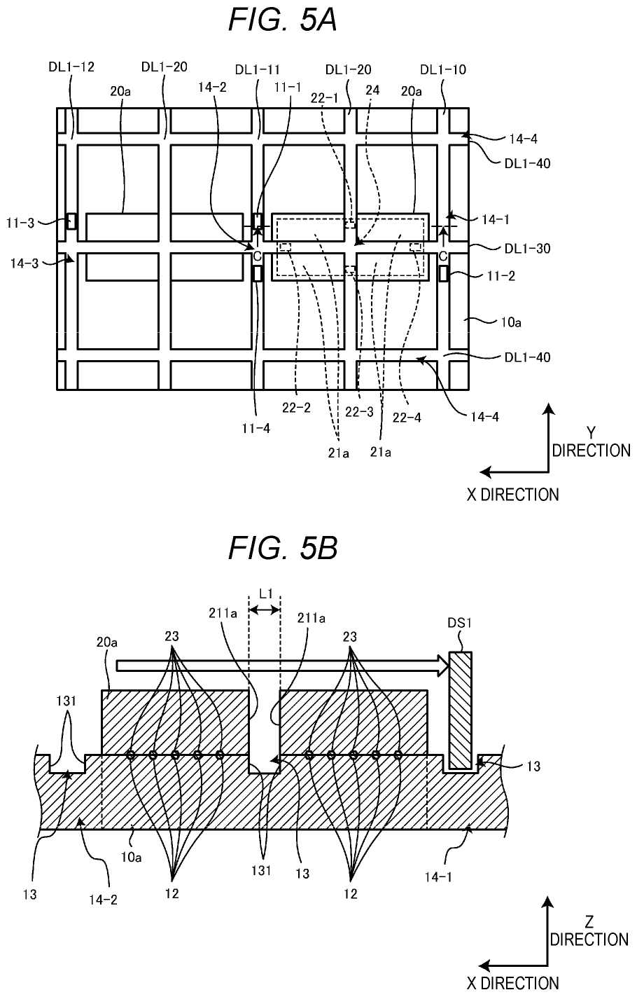

FIGS. 5A and 5B are diagrams illustrating a process of forming the recess 13 in the procedure of the manufacturing method of the semiconductor device 1a. FIG. 5A is a top view diagram of the substrate 10a, which illustrates an aspect that the recess 13 is formed along a dicing line DL1. FIG. 5B is an XZ cross-sectional diagram taken along the line C-C in FIG. 5A. It is to be noted that, in FIG. 5A, as a matter of convenience of description, a configuration, such as the alignment marks 11-1 to 11-4 and 22-1 to 22-4, that is not necessarily visible after formation of the recess 13 is also depicted.

As illustrated in FIG. 5A, the gap portions 14-1 to 14-4 of the substrate 10a and the boundary portion 24 of the composite cell substrate 20a are cut into in the stacked direction to form a recessed portion, and thereby the recess 13 is formed in the upper surface 140a of the substrate 10a.

Specifically, first, the substrate 10a is cut into at a predetermined depth from the positive Z direction side along a dicing line DL1-10 passing along the gap portion 14-1 of the substrate 10a and extending in the Y direction. At this time, a dicing saw DS1 is pressed so that the dicing line DL1-10 and the alignment mark 11-2 which is lined up in the gap portion 14-1 overlap in the up and down direction. Consequently, the alignment mark 11-2 is cut into as the recess 13 is formed.

The term predetermined depth used herein is a depth exceeding a depth at which a peripheral circuit is formed when observing the substrate 10a from the positive Z direction side. As long as the alignment mark 11-2 is cut into, it does not necessarily need to exceed the depth at which the peripheral circuit is formed. By cutting into the substrate 10a to the predetermined depth along the Y direction, the peripheral circuits formed on the substrate 10a are divided in the X direction.

Similarly, the substrate 10a is cut into along a dicing line DL1-11 passing along the gap portion 14-2 of the substrate 10a and extending in the Y direction. At this time, the dicing saw DS1 is pressed so that the dicing line DL1-11 and the alignment marks 11-1 and 11-4 lined up in the gap portion 14-2 overlap in the up and down direction. Consequently, the alignment marks 11-1 and 11-4 are cut into as the recess 13 is formed.

Similarly, the substrate 10a is cut into along a dicing line DL1-12 passing along the gap portion 14-3 of the substrate 10a and extending in the Y direction. Consequently, the alignment mark 11-3 is cut into.

Next, the substrate 10a is cut into along dicing lines DL1-20 each passing along the boundary portion 24 of the composite cell substrate 20a and extending in the Y direction. At this time, the dicing saw DS1 is pressed so that the dicing line DL1-20 and the alignment marks 22-1 and 22-3 lined up in the boundary portion 24 overlap in the up and down direction. Consequently, the alignment marks 22-1 and 22-3 are cut into as the recess 13 is formed.

Moreover, at this time, as illustrated in FIG. 5B, as the formation of the recess 13, adjacent cells 21a provided on the composite cell substrate 20a are divided in the X direction, and side surfaces 211a of the cells 21a are exposed. Consequently, when viewed in the stacked direction, the side surface 211a of the cell 21a and the side surfaces 131 of the recess 13 are located on the same plane.

Similarly, the substrate 10a is cut into along dicing lines DL1-30 each passing along the boundary portion 24 and extending in the X direction. At this time, the dicing saw DS1 is pressed so that the dicing line DL1-30 and the alignment marks 22-2 and 22-4 lined up in the boundary portion 24 overlap in the up and down direction. Consequently, the alignment marks 22-2 and 22-4 are cut into as the recess 13 is formed.

Moreover, at this time, although not illustrated, as the formation of the recess 13, adjacent cells 21a provided on the composite cell substrate 20a are divided in the Y direction, and side surfaces 212 of the cells 21a are exposed. Consequently, when viewed in the stacked direction, the side surfaces 212 of the cell 21a and the side surface 131 of the recess 13 are located on the same plane.

Furthermore, the substrate 10a is cut into in the stacked direction along a dicing line DL1-40 passing along the gap portion 14-4 and extending in the X direction.

The recess 13 extending in the X direction and the Y direction in the substrate 10a and having the predetermined depth is formed by performing the process illustrated in FIGS. 5A and 5B.

It is to be noted that when forming the recess 13, the dicing saw DS1 having substantially the same width as the width of the boundary portion 24 is used, but it is not limited thereto. For example, a dicing saw having substantially the same width as that of the gap portion 14-2 or the like may be used.

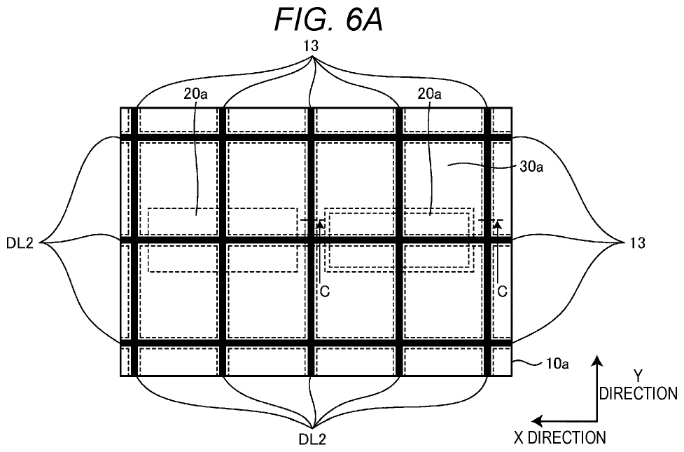

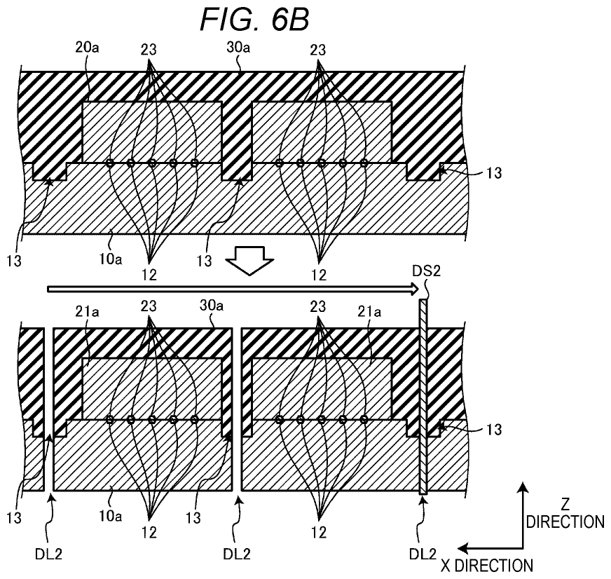

FIGS. 6A and 6B are diagrams illustrating a process of individualizing the cells 21a in the procedure of the manufacturing method of the semiconductor device 1a. FIG. 6A is a top view diagram of the substrate 10a, which illustrates an aspect that the cells 21a are individualized along dicing lines DL2. FIG. 6B is an XZ cross-sectional diagram taken along the line C-C in FIG. 6A.

As illustrated in the upper diagram of FIG. 6B, prior to individualizing the cells 21a, the sealing member 30a is formed to cover the substrate 10a and the composite cell substrate 20a. Consequently, the substrate 10a, the composite cell substrate 20a, and the recess 13 are covered by the sealing member 30a.

As illustrated in FIG. 6A and the lower diagram of FIG. 6B, a dicing saw DS2 is pressed from the positive Z direction side along the dicing line DL2 passing along a portion inside the recess 13 and extending in both the X direction and the Y direction to cut out the substrate 10a in the stacked direction. Consequently, each cell 21a is individualized.

When cutting out the substrate 10a, the dicing saw DS2 having a width narrower than a width of the recess 13 is used. Consequently, each cell 21a is individualized in a state of the sealing member 30a is left on the side surface thereof.

The semiconductor device 1a is manufactured through the above-described process.

It is to be noted that, for the above-described formation of the recess 13 and the above-described individualization cell 21a, for example, laser processing, plasma processing, or the like may be used instead of the blade processing using the dicing saws DS1 and DS2.

### Comparative Example

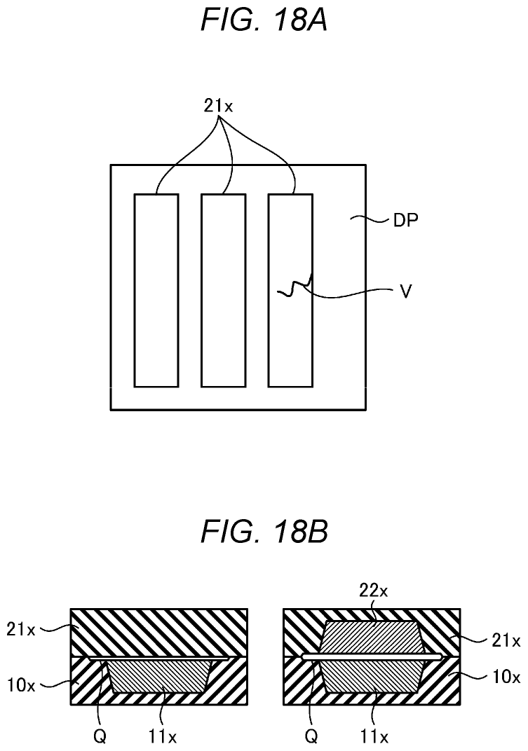

A semiconductor device according to a comparative example will be described with reference to FIGS. 18A and 18B. FIGS. 18A and 18B are diagrams illustrating a part of a manufacturing method of the semiconductor device according to the comparative example.

As illustrated in FIG. 18A, in the manufacturing process of the semiconductor device according to the comparative example, cells 21x individually picked up by a picker or the like from a dicing tape DP are mounted in a substrate which is a mounting target. When picking up the cell 21x from dicing tape DP, a crack V may occur in the cell 21x, or the cell 21x may be tilted. This is because a film thickness of the cell 21x is thin and a long side of the cell 21x is longer than a short side, making it difficult to maintain balance in the horizontal direction. When such a pickup failure occurs, an electrical connection between the cell 21x and the substrate which is the mounting target is inhibited, and a yield of the semiconductor device may be reduced.

Moreover, in the manufacturing process of the semiconductor device according to the comparative example, a long processing time may be required for mounting the cell 21x. This is because it is necessary to individually align the cell 21x with respect to the substrate which is the mounting target. Consequently, productivity of the semiconductor device may be reduced.

Moreover, as illustrated in FIG. 18B, in the manufacturing process of the semiconductor device according to the comparative example, when the cell 21x is mounted on a substrate 10x which is the mounting target, an alignment mark 11x formed in the substrate 10x and an alignment mark 22x formed in the cell 21x are used. At this time, voids Q may occur on a contact surface between the substrate 10x and the cell 21x at locations where the alignment mark 11x and the alignment mark 22x are formed.

The alignment marks 11x and 22x have a large surface area exposed on the substrate surface than that of a terminal and the like. Moreover, copper (Cu) or the like embedded in the alignment marks 11x and 22x is softer than an insulating film or the like forming the substrate 10x and a substrate surface of the cell 21x. Accordingly, when the substrate 10a and the substrate surface of the cell 21x are polished, recesses called dishing and thinning respectively may occur in the copper (Cu) embedded in the alignment marks 11x and 22x and the insulating film or the like of the peripheral edge of the copper (Cu). This is because the locations where the alignment marks 11x and 22x are formed are excessively polished.

When the substrate 10x and the cell 21x respectively having such recesses are brought into contact with each other and then are subjected to a heating process or the like, voids Q are formed in the contact surface therebetween. Reliability of the semiconductor device may be reduced due to the formation of voids Q.

### Outline

According to the manufacturing method of the semiconductor device 1a, the composite cell substrates 20a including a plurality of cells 21a adjacent to each other via the boundary portion 24 are mounted on the substrate 10a at the predetermined intervals. The sealing member 30a is formed to cover the substrate 10a and the composite cell substrate 20a, and the substrate 10a is cut out in the stacked direction to individualize the cells 21a.

Thus, since the composite cell substrate 20a including a plurality of cells 21a is mounted on the substrate 10a and then the cells 21a are individualized, it is not necessary to pick up each cell 21a individually. Consequently, it is possible to avoid pickup failures of the cell 21a and thereby the yield of the semiconductor device 1a can be improved. Moreover, it is not necessary to individually align the cell 21a with respect to the substrate 10a and thereby the productivity of the semiconductor device 1a can be improved.

Moreover, according to the manufacturing method of the semiconductor device 1a, after mounting the composite cell substrate 20a on the substrate 10a, the gap portion 14 of the substrate 10a and the boundary portion 24 of the composite cell substrate 20a are cut into at the predetermined depth in the stacked direction, to form the recess 13. Then, the sealing member 30a is formed and the inside of the recess 13 is cut out in the stacked direction to individualize each cell 21a.

Consequently, a contact time of the dicing saw DS2 is reduced with respect to the side surfaces 211a to 212 of the cell 21a and the side surface 131 of the substrate 10a, each exposed as the formation of the recess 13. Accordingly, it is possible to reduce a damage caused by the dicing saw DS2 to the cell 21a and the substrate 10a.

Moreover, a leg portion of the sealing member 30a is formed by the formation of the recess 13 to be inserted into the recess 13, the adhesion between the substrate 10a and cell 21a and the sealing member 30a is further improved.

Moreover, according to the manufacturing method of the semiconductor device 1a, the alignment mark 11 and the alignment mark 22 are respectively formed inside the gap portion 14 of the substrate 10a and inside the boundary portion 24 of the composite cell substrate 20a. Then, when the recess 13 is formed, the alignment marks 11 and 22 are cut into.

Consequently, since the alignment mark is removed from the contact surface between the substrate 10a and the composite cell substrate 20a, thereby avoiding the formation of the voids Q, and as a result, the reliability of the semiconductor device 1a can be improved.

According to the manufacturing method of the semiconductor device 1a, the alignment marks 11-1 and 11-2 are formed to be diagonal to each other outside the mounting region of the composite cell substrate 20a. Moreover, the alignment marks 22-1 to 22-4 are respectively formed in the XY directions on the composite cell substrate 20a at positions apart from one another.

Thus, by mounting the composite cell substrate 20a having a relatively large area on the substrate 10a, it is possible to make, for example, a distance between the alignment marks 11-1 and 11-2, a distance between the alignment marks 22-1 and 22-3, and a distance between the alignment mark 22-2 and 22-4 large. Consequently, it is possible to improve accuracy of the position alignment of the composite cell substrate 20a with respect to the substrate 10a.

### Modified Example 1

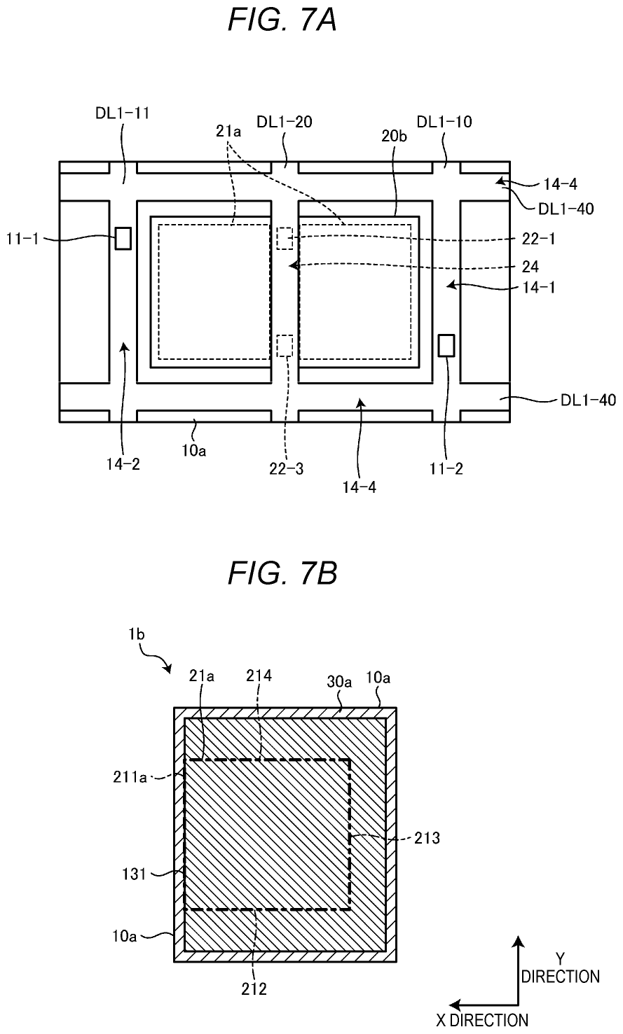

A manufacturing method of a semiconductor device 1b according to a modified example 1 will be described with reference to FIGS. 7A and 7B. FIGS. 7A and 7B are diagrams illustrating a part of the manufacturing method of the semiconductor device 1b according to the modified example 1. FIG. 7A is a top view diagram in the manufacturing method of the semiconductor device 1b according to the modified example 1, corresponding to FIG. 5A. FIG. 7B is an XY cross-sectional diagram in the semiconductor device 1b according to the modified example 1, corresponding to FIG. 1B. It is to be noted that, in FIG. 7A, as a matter of convenience of description, a configuration, such as the alignment marks 11-1, 11-2, 22-1, and 22-3, that is not necessarily visible after formation of the recess 13 is also depicted.

The manufacturing method of the semiconductor device 1b according to the modified example 1 differs from the embodiment described above in that the cells 21a are arranged in line in only any one of the X direction and the Y direction in a composite cell substrate 20b via the boundary portion 24. In the following, the same reference sign are applied to the same configuration as in the above-described embodiment, and the description thereof may be omitted.

As illustrated in FIG. 7A, the composite cell substrate 20b includes a boundary portion 24 extending only in the Y direction, and two cells 21a adjacent to each other in the X direction via the boundary portion 24. Moreover, alignment marks 22-1 and 22-3 are formed inside the boundary portion 24.

In the manufacturing method of the semiconductor device 1b according to the modified example 1, the substrate 10a is cut into in the stacked direction along the dicing line DL 1-20 passing along the boundary portion 24 extending only in the Y direction, to form the recess 13. The substrate 10a and the composite cell substrate 20b are covered by the sealing member 30a, and a portion inside the recess 13 is cut out in the stacked direction. Through such a procedure, two semiconductor devices 1b are manufactured.

As illustrated in FIG. 7B, in the semiconductor device 1b manufactured as described above, when viewed in the stacked direction, only one side surface 211a of the cell 21a is located on the same plane as the side surface 131, and the side surfaces 212 to 214 are located inside the side surface 131.

According to the manufacturing method of the semiconductor device 1b, and the semiconductor device 1b according to the modified example 1, the same advantageous effects are produced as the manufacturing method of the semiconductor device 1a, and the semiconductor device 1a according to the above-described embodiment.

### Modified Example 2

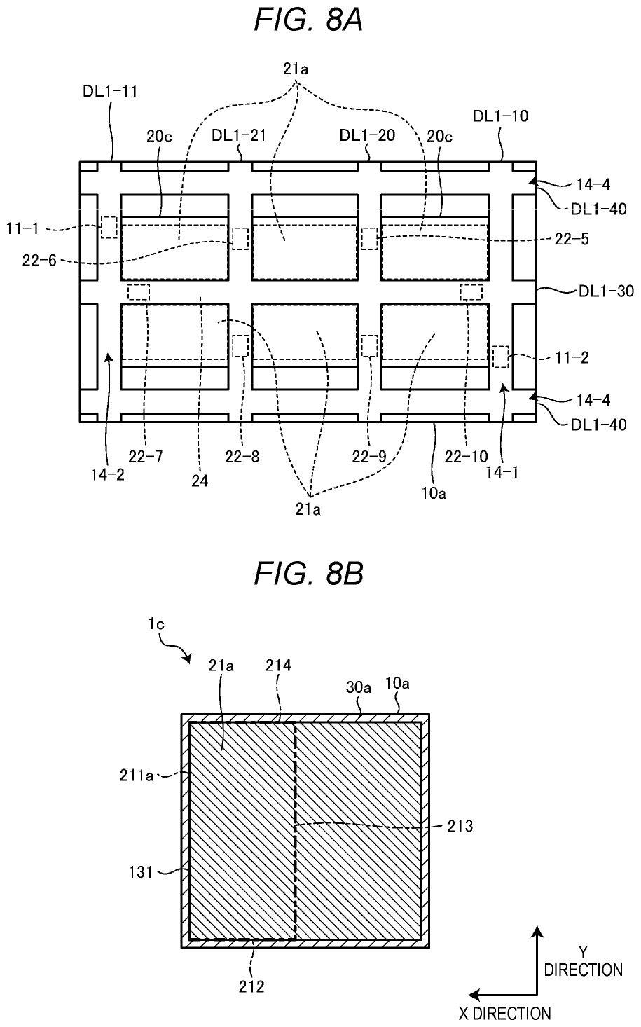

A manufacturing method of a semiconductor device 1c according to a modified example 2 of the embodiment will be described with reference to FIGS. 8A and 8B. FIGS. 8A and 8B are diagrams illustrating a part of the manufacturing method of the semiconductor device 1c according to the modified example 2. FIG. 8A is a top view diagram in the manufacturing method of the semiconductor device 1c according to the modified example 2, corresponding to FIG. 5A. FIG. 8B is an XY cross-sectional diagram in the semiconductor device 1c according to the modified example 2, corresponding to FIG. 1B. It is to be noted that, in FIG. 8A, as a matter of convenience of description, a configuration, such as the alignment marks 11-1, 11-2, and 22-5 to 22-10, that is not necessarily visible after formation of the recess 13 is also depicted.

The manufacturing method of the semiconductor device 1c according to the modified example 2 differs from the embodiment described above in that three or more cells 21a are arranged in line in any one of the X direction and the Y direction in a composite cell substrate 20c via the boundary portion 24. In the following, the same reference sign are applied to the same configuration as in the above-described embodiment, and the description thereof may be omitted.

As illustrated in FIG. 8A, the composite cell substrate 20b includes a boundary portion 24 extending in the X direction and the Y direction, and three cells 21a adjacent to one another in the X direction and two cells 21a adjacent to each other in the Y direction via the boundary portion 24. Moreover, alignment marks 22-5 to 22-10 are formed inside the boundary portion 24.

In the manufacturing method of the semiconductor device 1c according to the modified example 2, the substrate 10a is cut into in the stacked direction along dicing lines DL1-20 and DL1-21 respectively passing along the plurality of boundary portions 24 extending in the Y direction, to form the recess 13. The substrate 10a and the composite cell substrate 20b are covered by the sealing member 30a, and a portion inside the step height 13 is cut out in the stacked direction. Through such a procedure, six semiconductor devices 1c are manufactured.

As illustrated in FIG. 8B, in the semiconductor device 1c manufactured as described above, when viewed in the stacked direction, three side surfaces 211a to 213 of the cell 21a are located on the same plane as the side surface 131. The side surface 214 is located inside the side surface 131.

According to the manufacturing method of the semiconductor device 1c, and the semiconductor device 1c according to the modified example 2, the same advantageous effects are produced as the manufacturing method of the semiconductor device 1a, and the semiconductor device 1a according to the above-described embodiment.

### Modified Example 3

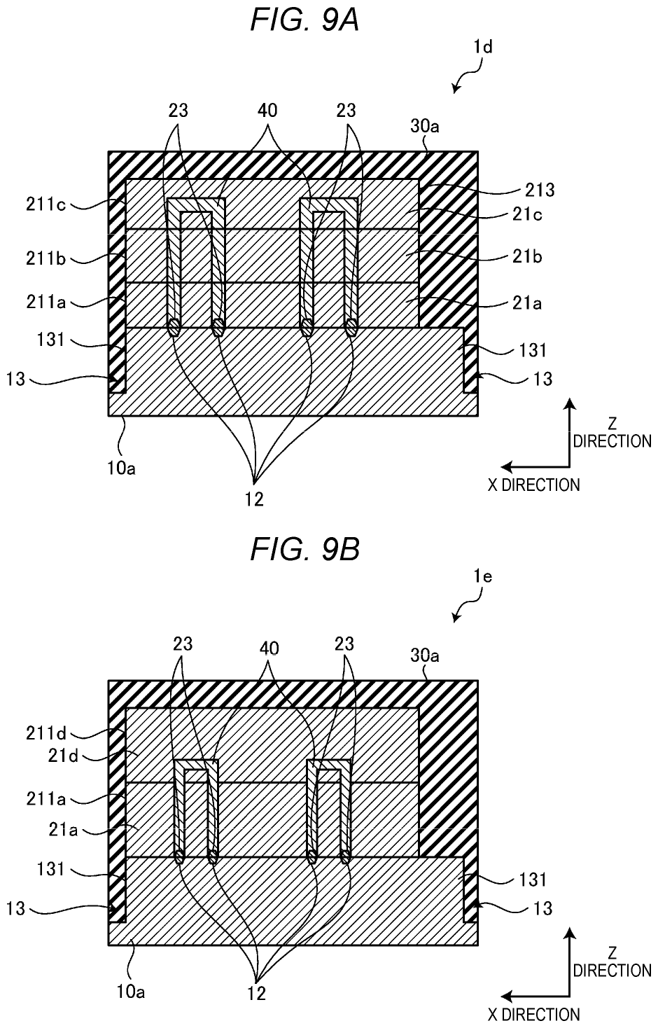

Semiconductor devices 1d and 1e according to a modified example 3 will be described with reference to FIGS. 9A and 9B. FIG. 9A is a diagram illustrating a configuration of the semiconductor device 1d according to the modified example 3. FIG. 9B is a diagram illustrating a configuration of the semiconductor device 1e according to the modified example 3.

The semiconductor devices 1d and 1e according to the modified example 3 differ from the embodiment described above in that a plurality of cells 21 as the semiconductor cells are stacked on the substrate 10a. In the following, the same reference sign are applied to the same configuration as in the above-described embodiment, and the description thereof may be omitted.

As illustrated in FIG. 9A, in the semiconductor device 1d according to the modified example 3, a plurality of cells 21a to 21c having the same shape are stacked on the upper surface 140a of the substrate 10a. A wiring 40 extends in the stacked direction inside the cells 21a to 21c, and the wiring 40 is connected to the substrate 10a via the terminal 23 and the terminal 12. At this time, when viewed in the stacked direction, and a side surface 211a of the cell 21a, a side surface 211b of the cell 21b, and a side surface 211c of the cell 21c are disposed on the same plane as the side surface 131 of the recess 13.

As illustrated in FIG. 9B, in the semiconductor device 1e according to the modified example 3, a plurality of cells 21a and 21d having different shapes from each other are stacked on the upper surface 140a of the substrate 10a. At this time, when viewed in the stacked direction, and the side surface 211a of the cell 21a and a side surface 211d of the cell 21d are disposed on the same plane as the side surface 131 of the recess 13.

According to the semiconductor devices 1d and 1e according to the modified example 3, the same advantageous effects are produced as the manufacturing method of the semiconductor device 1a, and the semiconductor device 1a according to the above-descried embodiment.

### Modified Example 4

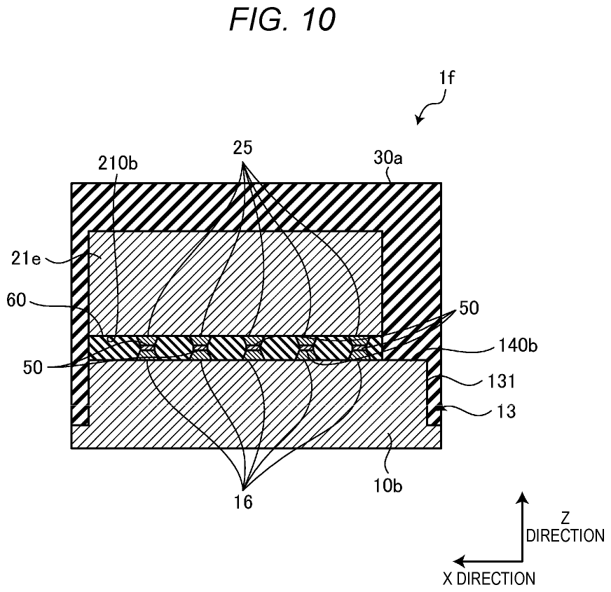

A semiconductor device if according to a modified example 4 of the embodiment will be described with reference to FIG. 10. FIG. 10 is a diagram illustrating a configuration of the semiconductor device if according to the modified example 4.

The semiconductor device if according to the modified example 4 differs from the embodiment described above in that a substrate 10b and a cell 21e are bonded via a bump. In the following, the same reference sign are applied to the same configuration as in the above-described embodiment, and the description thereof may be omitted.

Bumps 16 and bumps 25 as electrodes are respectively arranged in an array on an upper surface 140b of the substrate 10b and a substrate surface 210b of the cell 21e. The bump 16 and the bump 25 are bonded to each other via a solder 50. Consequently, the substrate 10b and the cell 21e are electrically connected to each other.

Moreover, an adhesive 60 is filled between the substrate 10b and the cell 21e. The adhesive 60 includes, for example, an epoxy resin, such as a Non Conductive Film (NCF), a Non Conductive Paste (NCP), or a mold material. Consequently, a mounting surface between the substrate 10b and the cell 21e is protected.

According to the semiconductor device if according to the modified example 4, in addition thereto, the same advantageous effects are produced as the manufacturing method of the semiconductor device 1a, and the semiconductor device 1a according to the above-descried embodiment.

### Modified Example 5

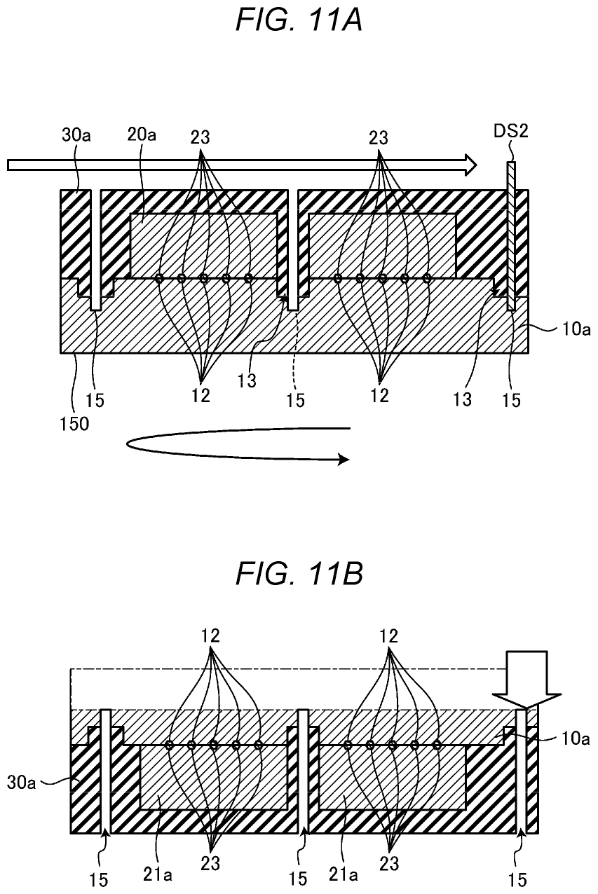

A manufacturing method of a semiconductor device according to a modified example 5 will be described with reference to FIGS. 11A and 11B. FIGS. 11A and 11B are diagrams illustrating a part of the manufacturing method of the semiconductor device according to the modified example 5.

The manufacturing method of the semiconductor device according to the modified example 5 differs from the embodiment described above in that, when individualizing the cells 21a, a polishing process is used in addition to the blade process using the dicing saw DS2. In the following, the same reference sign are applied to the same configuration as in the above-described embodiment, and the description thereof may be omitted.

As illustrated in FIG. 11A, in the manufacturing method of the semiconductor device according to the modified example 5, the substrate 10a and the composite cell substrate 20a are covered by the sealing member 30a after formation of the recess 13. Then, instead of cutting out of the substrate 10a, the inside portion of the recess 13 is cut into to a predetermined depth to form a recessed portion 15 inside the recess 13. Moreover, as illustrated in FIG. 11B, the bottom surface 150 of the substrate 10a is polished until the recessed portion 15 is opened. Consequently, each cell 21a is individualized.

In the manufacturing method of the semiconductor device according to the modified example 5, the predetermined depth is assumed to be a value that matches, but is not limited to, a thickness finally required for the substrate 10a when the semiconductor device is manufactured. That is, the predetermined depth may be any value as long as the depth does not exceed a thickness of the substrate 10a.

When manufacturing the semiconductor device, the thickness may be adjusted by polishing the bottom surface 150 of the substrate 10a, before cutting out the substrate 10a. In such a case, strength of the semiconductor device may decrease due to thinning of the substrate 10a, and the semiconductor device may be damaged during the cutting-out process using the dicing saw DS2. Therefore, the substrate 10a is cut into in advance to the depth that matches the thickness finally required for the substrate 10a and then the substrate 10a is cut out by polishing the bottom surface 150 of the substrate 10a. Consequently, damage of the semiconductor device is prevented.

According to the manufacturing method of the semiconductor device according to the modified example 5, in addition thereto, the same advantageous effects are produced as the manufacturing method of the semiconductor device, and the semiconductor device according to the above-descried embodiment.

### Modified Example 6

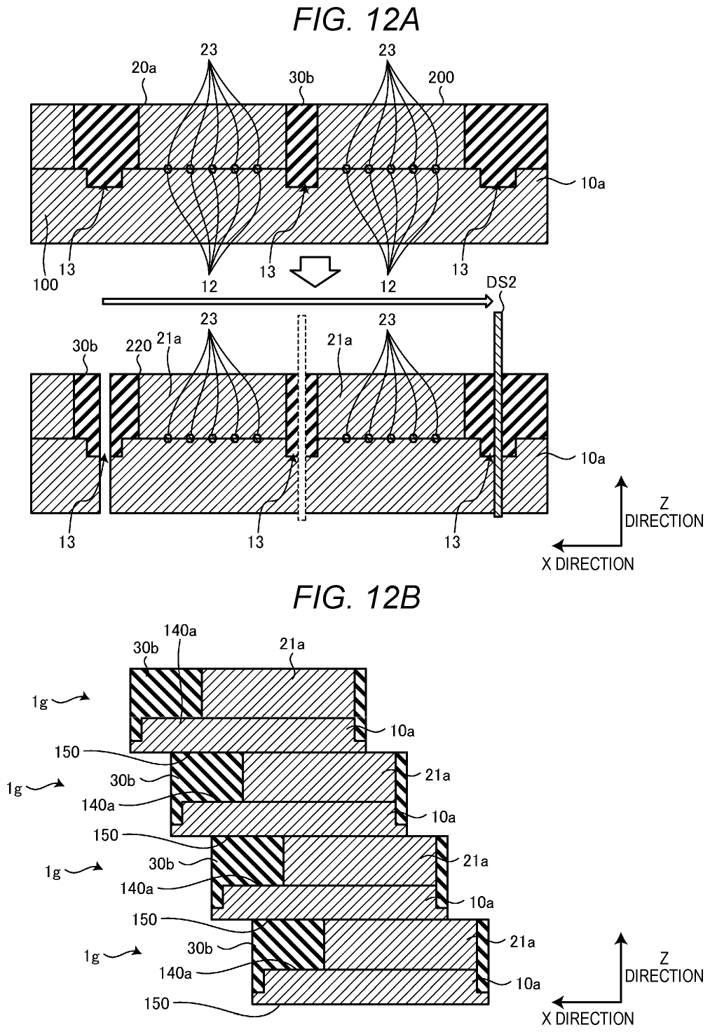

A manufacturing method of a semiconductor device 1g according to a modified example 6 will be described with reference to FIGS. 12A and 12B. FIGS. 12A and 12B are diagrams respectively illustrating a part of the manufacturing method of the semiconductor device 1g according to the modified example 6, and an application example of the semiconductor device 1g. FIG. 12A is an XZ cross-sectional diagram in the manufacturing method of the semiconductor device 1g according to the modified example 6, corresponding to FIG. 6B. FIG. 12B is a diagram illustrating an application example of the semiconductor device 1g according to the modified example 6.

The manufacturing method of the semiconductor device 1g according to the modified example 6 differs from the embodiment described above in that the composite cell substrate 20a is not completely covered by a sealing member 30b. In the following, the same reference sign are applied to the same configuration as in the above-described embodiment, and the description thereof may be omitted.

As illustrated in FIG. 12A, in the manufacturing method of the semiconductor device 1g according to the modified example 6, the sealing member 30b is formed at a height that matches an upper surface 200 of the composite cell substrate 20a, after the process illustrated in FIG. 5. Then, a portion inside the recess 13 is cut into in the stacked direction to individualize the cell 21a. In the semiconductor device 1g manufactured in this manner, an upper surface of the cell 21a is exposed.

As illustrated in FIG. 12B, the semiconductor devices 1g manufactured in this manner is applicable as a semiconductor package in which each is stacked while being sequentially shifted in the X direction and sealed in a collective manner. At this time, the sealing member 30b is disposed, for example, between the bottom surface 150 of the semiconductor device 1g and the upper surface 140a of the semiconductor device 1g disposed below thereof. Consequently, with respect to a stress applied to positive and negative directions of Z, the plurality of stacked semiconductor devices 1g are supported to each other. At this time, for example, a spacer or the like may be used instead of the resin film, as the sealing member 30b.

### Modified Example 7

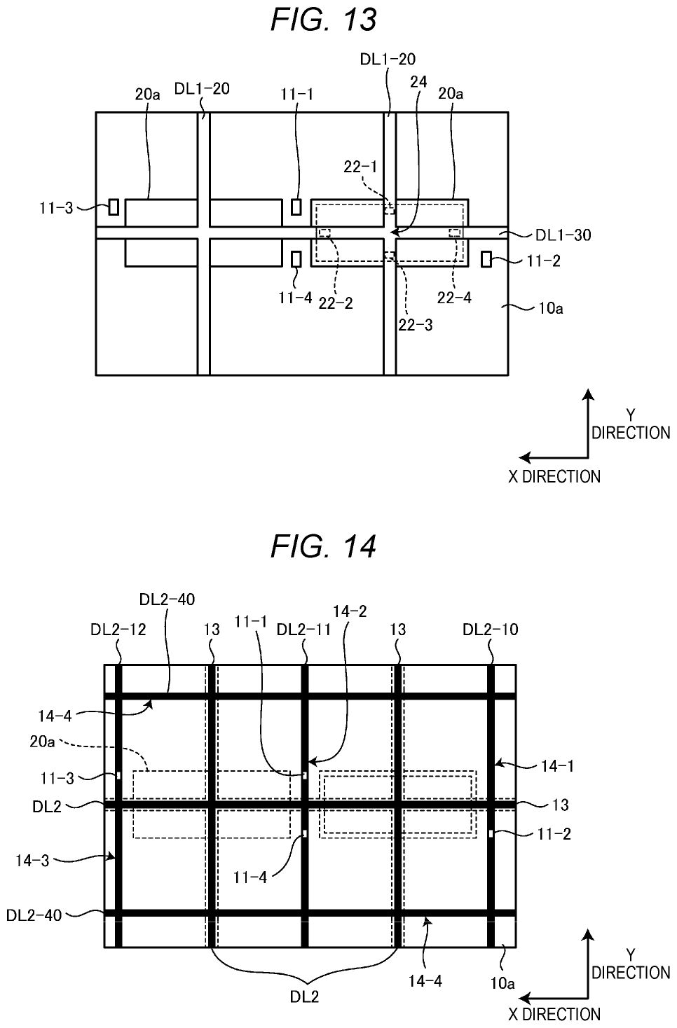

A manufacturing method of a semiconductor device 1h, and the semiconductor device 1h according to a modified example 7 will be described with reference to FIGS. 13 to 15.

FIGS. 13 to 14 are diagrams illustrating parts of the manufacturing method of the semiconductor device 1h according to the modified example 7. FIG. 13 is a top view diagram in the manufacturing method of the semiconductor device 1h according to the modified example 7, corresponding to FIG. 5A. FIG. 14 is a top view diagram in the manufacturing method of the semiconductor device 1h according to the modified example 7, corresponding to FIG. 6A. It is to be noted that, in FIG. 13, as a matter of convenience of description, a configuration, such as the alignment marks 22-1 to 22-4, that is not necessarily visible after formation of the recess 13 is also depicted. Similarly in FIG. 14, a configuration, such as the alignment marks 11-1 to 11-4, that is not necessarily visible after cutting-out of the substrate 10a is also depicted.

The manufacturing method of the semiconductor device 1h of the modified example 7 different from the embodiment described above in that only the boundary portion 24 of the composite cell substrate 20a is cut into in the stacked direction to form a recessed portion, when forming the recess 13. In the following, the same reference sign are applied to the same configuration as in the above-described embodiment, and the description thereof may be omitted.

Specifically, as illustrated in FIG. 13, first, the substrate 10a is cut into along dicing lines DL1-20 each passing along the boundary portion 24 of the composite cell substrate 20a and extending in the Y direction. Consequently, the alignment marks 22-1 and 22-3 are cut into as the recess 13 is formed.

Similarly, the substrate 10a is cut into along dicing lines DL1-30 each passing along the boundary portion 24 and extending in the X direction. Consequently, the alignment marks 22-2 and 22-4 are cut into as the recess 13 is formed.

Next, although not illustrated, the sealing member 30a is formed to cover the substrate 10a and the composite cell substrate 20a.

Then, as illustrated in FIG. 14, the substrate 10a is cut out in the stacked direction along a dicing line DL2-10 passing along the gap portion 14-1 of the substrate 10a and extending in the Y direction. At this time, the dicing saw DS2 is pressed so that the dicing line DL2-10 and the alignment mark 11-2 overlap in the up and down direction. Consequently, the alignment mark 11-2 is removed and the substrate 10a is divided in the X direction.

Similarly, the substrate 10a is cut out in the stacked direction along a dicing line DL2-11 passing along the gap portion 14-2 of the substrate 10a and extending in the Y direction. At this time, a dicing saw DS2 is pressed so that the dicing line DL2-11 and the alignment marks 11-1 and 11-4 lined up in the gap portion 14-2 overlap in the up and down direction. Consequently, the alignment marks 11-1 and 11-4 are removed and the substrate 10a is divided in the X direction.

Similarly, the substrate 10a is cut out in the stacked direction along a dicing line DL2-12 passing along the gap portion 14-3 of the substrate 10a and extending in the Y direction. At this time, the dicing saw DS2 is pressed so that the dicing line DL2-12 and the alignment mark 11-3 overlap in the up and down direction. Consequently, the alignment mark 11-3 is removed and the substrate 10a is divided in the X direction.

Furthermore, the substrate 10a is cut out in the stacked direction along a dicing line DL2-40 passing along the gap portion 14-4 and extending in the X direction. Consequently, the substrate 10a is divided in the Y direction.

The cells 21a are individualized through the above-described process. Through such a procedure, the semiconductor device 1h is manufactured.

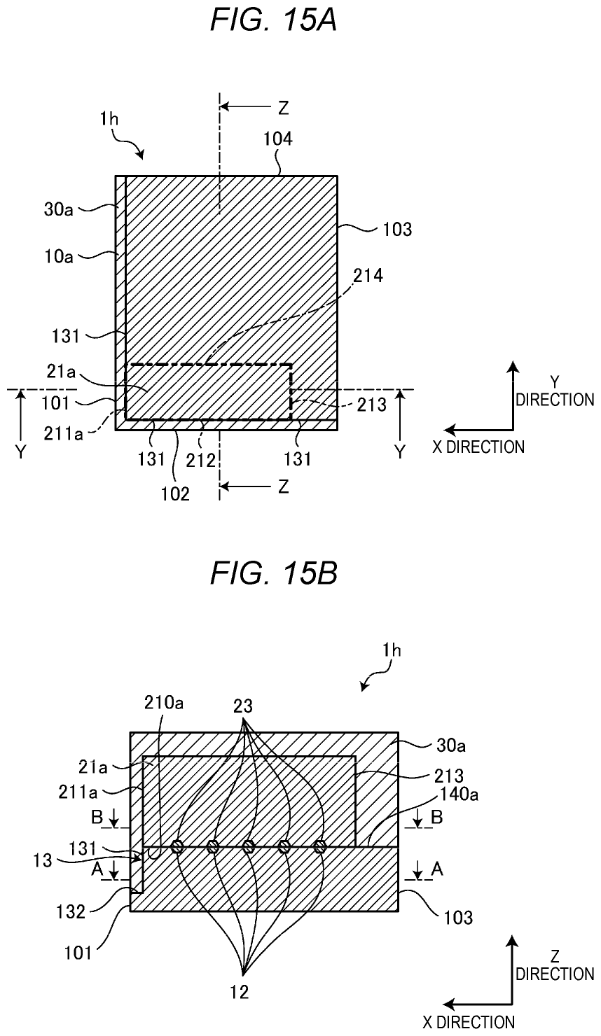

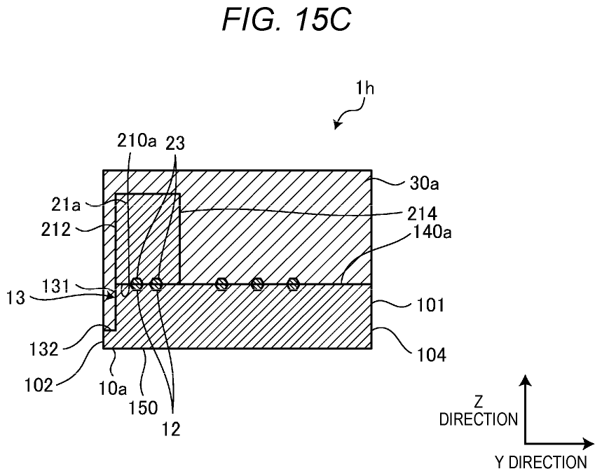

FIGS. 15A, 15B, and 15C are diagrams illustrating a configuration of the semiconductor device 1h according to the modified example 7. FIG. 15A is an XY cross-sectional diagram corresponding to FIG. 1B. FIG. 15B is an XZ cross-sectional diagram taken along the line Y-Y in FIG. 15A, corresponding to FIG. 1A. FIG. 15C is a YZ cross-sectional diagram taken along the line Z-Z in FIG. 15A.

As illustrated in FIG. 15A, the side surfaces 101 to 104 form the outer peripheral portion of the substrate 10a in the semiconductor device 1h manufactured as described above. Among the side surfaces 101 to 104, the recess 13 is formed only in the side surfaces 101 and 102 that are adjacent to each other. The recess 13 has the side surface 131. Accordingly, as illustrated in FIGS. 15B and 15C, when viewed in the stacked direction, the side surfaces 211a to 212 of the cell 21a are respectively located on the same plane as the side surfaces 131.

### Modified Example 8

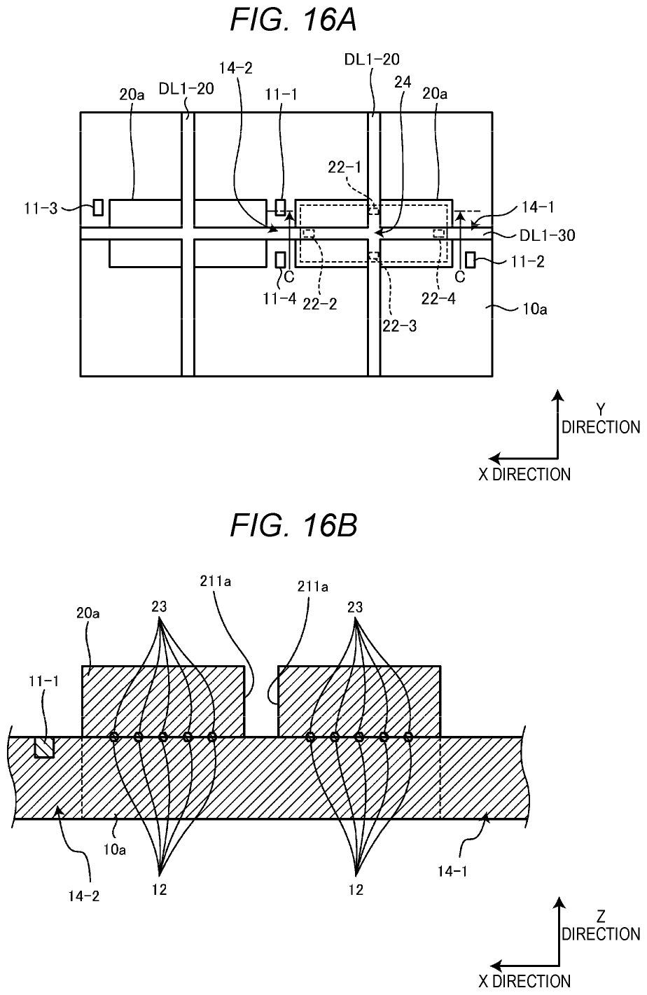

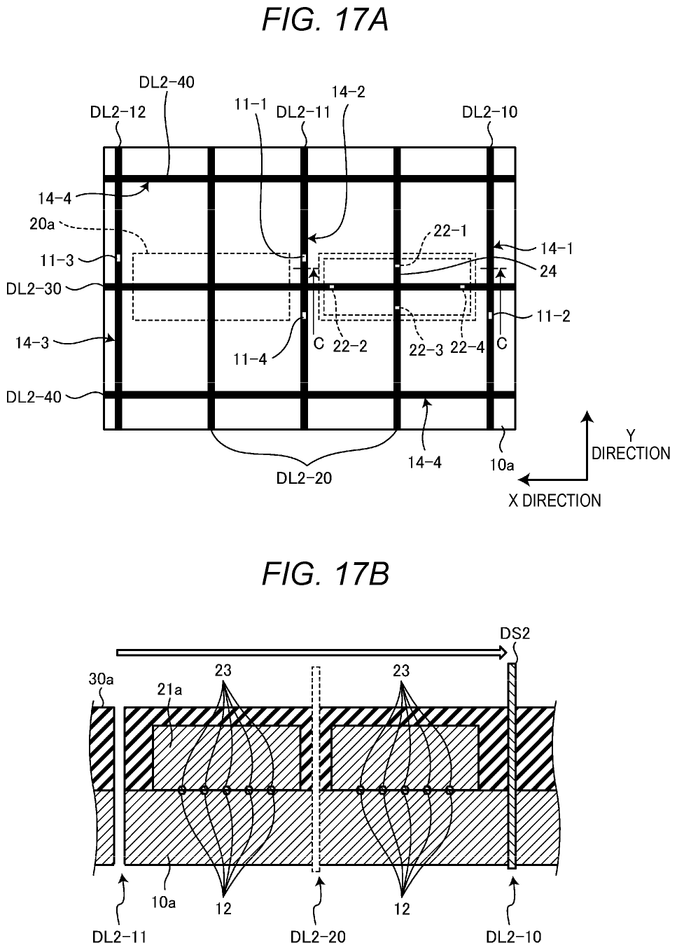

A manufacturing method of a semiconductor device 1i according to a modified example 8 will be described with reference to FIGS. 16 to 17. FIGS. 16 to 17 are diagrams illustrating parts of the manufacturing method of the semiconductor device 1i according to the modified example 8. FIG. 16A is a top view diagram in the manufacturing method of the semiconductor device 1i according to the modified example 8, corresponding to FIG. 5A. FIG. 16B is an XZ cross-sectional diagram taken along the line C-C in FIG. 16A. FIG. 17A is a top view diagram in the manufacturing method of the semiconductor device 1i according to the modified example 8, corresponding to FIG. 6A. FIG. 17B is an XZ cross-sectional diagram taken long the line D-D in FIG. 16A. It is to be noted that, in FIG. 16A, as a matter of convenience of description, a configuration, such as the alignment marks 22-1 to 22-4, that is not necessarily visible after cutting-out of the composite cell substrate 20a is also depicted. Similarly in FIG. 17A, a configuration, such as the alignment marks 11-1 to 11-4 and 22-1 to 22-4, that is not necessarily visible after cutting-out of the substrate 10a is also depicted.

The manufacturing method of the semiconductor device 1i according to the modified example 8 differs from the embodiment described above in that no recess 13 is formed. In the following, the same reference sign are applied to the same configuration as in the above-described embodiment, and the description thereof may be omitted.

The substrate 10a and the composite cell substrate 20a are connected to each other. As illustrated in FIG. 16A, the composite cell substrate 20a is cut into in the stacked direction along dicing lines DL1-20 and DL1-30 respectively passing along the boundary portions 24 of the composite cell substrate 20a. At this time, as illustrated in FIG. 16B, no recessed portion is formed on the front side surface of the substrate 10a. At this time, the alignment marks 22-1 to 22-4 formed in the composite cell substrate 20a may be removed therefrom. For example, laser processing, plasma processing, or blade processing by a dicing saw is used for the cutting-into of the composite cell substrate 20a. Then, the sealing member 30a is formed to cover the substrate 10a and the composite cell substrate 20a.

After forming the sealing member 30a, as illustrated in FIGS. 17A and 17B, the substrate 10a is cut out in the stacked direction along the dicing line DL2-10 passing along the gap portion 14-1 of the substrate 10a and extending in the Y direction. Consequently, the alignment mark 11-2 is removed and the substrate 10a is divided in the X direction.

Similarly, the substrate 10a is cut out in the stacked direction along the dicing line DL2-11 passing along the gap portion 14-2 of the substrate 10a and extending in the Y direction. Consequently, the alignment marks 11-1 and 11-4 are removed and the substrate 10a is divided in the X direction.

Similarly, the substrate 10a is cut out in the stacked direction along the dicing line DL2-12 passing along the gap portion 14-3 of the substrate 10a and extending in the Y direction. Consequently, the alignment mark 11-3 is removed and the substrate 10a is divided in the X direction.

Next, the substrate 10a is cut out in the stacked direction along dicing lines DL2-20 each passing along the boundary portion 24 of the composite cell substrate 20a and extending in the Y direction. When the alignment marks 22-1 and 22-3 formed in the composite cell substrate 20a remain, the dicing saw DS2 is pressed so that the dicing line DL2-20 and the alignment marks 22-1 and 22-3 overlap in the up and down direction. Consequently, the alignment marks 22-1 and 22-3 are removed and the substrate 10a is divided in the X direction.

Similarly, the substrate 10a is cut out in the stacked direction along the dicing line DL2-30 passing along the boundary portion 24 and extending in the X direction. When the alignment marks 22-2 and 22-4 formed in the composite cell substrate 20a remain, the dicing saw DS2 is pressed so that the dicing line DL2-30 and the alignment marks 22-2 and 22-4 overlap in the up and down direction. Consequently, the alignment marks 22-2 and 22-4 are removed and the substrate 10a is divided in the Y direction.

Furthermore, the substrate 10a is cut out in the stacked direction along the dicing line DL2-40 passing along the gap portion 14-4 and extending in the X direction. Consequently, the substrate 10a is divided in the Y direction.

The cells 21a are individualized through the above-described process. Through such a procedure, the semiconductor device 1i is manufactured. As illustrated in FIG. 17B, no recess 13 is formed in the outer peripheral portion of the substrate 10a in the semiconductor device 1i manufactured as described above.

### Other Modified Examples

In the above-described embodiments and modified examples, no alignment mark is disposed in the planned mounting region PR1 and the planned mounting region PR2 on the substrate 10a. However, an alignment mark may be disposed in a portion where a predetermined dicing line overlaps the planned mounting region PR1 or the planned mounting region PR2. The alignment mark of the substrate 10a and the alignment mark of the composite cell substrate 20a may be located at corresponding positions and may be bond to each other. Even when the alignment marks are disposed in this manner, these alignment marks are removed during the formation of the recess 13 or the individualization of the substrate 10a.

In the above-described embodiments and modified examples, it is configured to remove the alignment mark 11 and the like as the formation of the recess 13. However, the alignment mark 11 and the like may be removed during the cutting-out of the substrate 10a.

In the above-described embodiments and modified examples, it is configured to arrange one cell 21a in the direction along the upper surface 140a of the substrate 10a, the arrangement of the cells 21a is not limited thereto. For example, two cells 21a may be arranged in the direction along the upper surface 140a of the substrate 10a. Moreover, the side surface 131 of the recess 13 formed in the outer peripheral portion of the substrate 10a and the side surface of each cell 21a may be disposed on the same plane.

In the above-described embodiments and modified examples, it is configured to cover at least a portion of the substrate 10a and the composite cell substrate 20a by the sealing member 30a or 30b after formation of the recess 13. However, it is not necessary to cover by the sealing member 30a or 30b. After each of the semiconductor devices manufactured in this manner may be stacked and then may be sealed in a collective manner.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A manufacturing method of a semiconductor device, the manufacturing method comprising:
mounting on a first substrate, a plurality of second substrates at a predetermined interval, the first substrate including a wiring layer, each of the second substrates including a plurality of semiconductor cells separated from each other by a boundary portion;
forming a first recess on the first substrate between two of the second substrates that are adjacent to each other;
cutting each of the second substrates along the boundary portion thereof to form a gap and a second recess on the first substrate through the gap;
forming a sealing member on the first substrate; and
cutting the first substrate together with the sealing member along lines extending along and inside the first and second recesses to individualize the semiconductor cells.

2. The manufacturing method of the semiconductor device according to claim 1, further comprising:
forming alignment marks for mounting the second substrates on the first substrate, wherein
forming the first recess includes removing the alignment marks.

3. The manufacturing method of the semiconductor device according to claim 1, wherein mounting the second substrates includes capturing an image of the first and second substrates and determining a mounting position of the second substrates using the alignment marks captured in the image.

4. The manufacturing method of the semiconductor device according to claim 3, wherein
each of the second substrates includes alignment marks between the semiconductor cells, and
mounting the second substrates includes determining a center position of each of the second substrates using the alignment marks thereof to determine the mounting position.

5. The manufacturing method of the semiconductor device according to claim 4, wherein cutting each of the second substrates includes removing the alignment marks thereof.

6. The manufacturing method of the semiconductor device according to claim 1, wherein each of the second substrates includes two or more semiconductor cells that are separated by the boundary portion in a first direction parallel to the second substrate.

7. The manufacturing method of the semiconductor device according to claim 6, wherein each of the second substrates includes two or more semiconductor cells that are separated by the boundary portion in a second direction perpendicular to the first direction.

8. The manufacturing method of the semiconductor device according to claim 1, wherein two or more of the semiconductor cells in each of the second substrates are stacked.

9. The manufacturing method of the semiconductor device according to claim 1, further comprising:
bonding each of the semiconductor cells to the first substrate via bumps.

10. The manufacturing method of the semiconductor device according to claim 1, wherein cutting the first substrate includes:
forming a third recess in each of the first and second recesses; and
polishing a part of the first substrate at a location corresponding to the third recess from a side on which the second substrates are not mounted.

11. The manufacturing method of the semiconductor device according to claim 1, wherein the sealing member covers the second substrates except for an upper surface thereof.

12. The manufacturing method of the semiconductor device according to claim 1, wherein the sealing member covers the first recess and side surfaces of semiconductor cells of the second substrates along which the first recess is formed.

13. The manufacturing method of the semiconductor device according to claim 1, wherein a side surface of each of the semiconductor cells extending along the second recess and a side surface of the second recess are on the same plane.

14. The manufacturing method of the semiconductor device according to claim 1, wherein
forming the first recess includes pressing a first dicing saw against the first substrate, and
forming the second recess includes pressing the first dicing saw against the boundary portion of the second substrate and then the first substrate.

15. The manufacturing method of the semiconductor device according to claim 14, wherein cutting the first substrate includes pressing a second dicing saw against a bottom surface of each of the first and second recesses, and a width of the second dicing saw is smaller than the first dicing saw.

16. A semiconductor device comprising:
a first substrate including a recess;
a first semiconductor cell mounted on the first substrate and surrounded by the recess; and
a sealing member covering the first substrate including the recess and the first semiconductor cell, wherein
the recess includes a side surface connected to a surface of the first substrate and a bottom surface connected to the side surface and extending substantially parallel to the surface of the first substrate,
the first semiconductor cell includes four side surfaces, and
the side surface of the recess and at least one of the four side surfaces of the first semiconductor cell are on the same plane, and the bottom surface of the recess and another one of the four side surfaces of the first semiconductor cell form a step portion therebetween.

17. The semiconductor device according to claim 16, further comprising:
a second semiconductor cell stacked on the first semiconductor cell.

18. The semiconductor device according to claim 16, wherein the semiconductor cell is mounted on the first substrate via an electrode formed on the surface of the first substrate.

19. The semiconductor device according to claim 16, wherein the side surface of the recess and each of two side surfaces of the first semiconductor cell that are connected to each other are on the same plane.

20. The semiconductor device according to claim 19, wherein the bottom surface of the recess and each of the other two side surfaces of the first semiconductor cell form the step portion.
